(19) United States
(12) Patent Application Publication
(10) Pub. No.: US 2025/0294838 A1
(43) Pub. Date: Sep. 18, 2025

(54) SEMICONDUCTOR DEVICES AND METHODS OF FABRICATING THE SAME

(71) Applicant: Taiwan Semiconductor Manufacturing Company, Ltd., Hsinchu (TW)

(72) Inventors: Iuliana Radu, Hsinchu (TW); Hung-Li Chiang, Hsinchu (TW); Hung-Chi Han, Hsinchu (TW); Jer-Fu Wang, Hsinchu (TW); Goutham Arutchelvan, Hsinchu (TW); Chao-Ching Cheng, Hsinchu (TW)

(73) Assignee: Taiwan Semiconductor Manufacturing Company, Ltd., Hsinchu (TW)

(21) Appl. No.: 18/604,058

(22) Filed: Mar. 13, 2024

(51) Int. Cl. H01L 29/15; G06N 10/40; H01L 23/498; H01L 29/08; H01L 29/66

(52) U.S. Cl. CPC H10D 62/815; G06N 10/40; H01L 23/49827; H10D 62/151; H10D 64/021

(57) ABSTRACT

A semiconductor device includes a first substrate having a first frontside and a first backside opposite the first frontside. The semiconductor device includes first source/drain (S/D) features over the first frontside. The semiconductor device includes a first barrier gate and a first plunger gate between the first S/D features, where the first plunger gate defines a first quantum bit region. The semiconductor device includes a second substrate having a second frontside and a second backside opposite the second frontside. The semiconductor device includes second S/D features over the second frontside. The semiconductor device includes a second barrier gate and a second plunger gate between the second S/D features, where the second plunger gate defines a second quantum bit region aligned with the first quantum bit region along the first direction. The semiconductor device includes a doped well extending between the first backside and the second backside along the first direction.

### BACKGROUND

Quantum computing refers to the field of research related to computation systems that use quantum mechanical phenomena to manipulate data. On the roadmap towards building a scalable, silicon-based quantum computer, several milestones have already been achieved. Quantum computing may involve initializing states of N qubits (quantum bits), creating controlled entanglements among them, allowing these states to evolve, and reading out the states of the qubits after the evolution. A qubit is a system having two degenerate (i.e., of equal energy) quantum states, with a non-zero probability of being found in either state. Thus, N qubits can define an initial state that is a combination of 2N classical states. While existing technologies related to silicon-based devices configured to quantum computing have been generally adequate, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of an example semiconductor device, in accordance with some embodiments of the present disclosure.

FIG. 2A is a cross-sectional view of the example semiconductor device of FIG. 1 along line A-A′, in accordance with some embodiments of the present disclosure.

FIG. 2B is a cross-sectional view of the example semiconductor device of FIG. 1 along line B-B′, in accordance with some embodiments of the present disclosure.

FIG. 2C is a cross-sectional view of the example semiconductor device of FIG. 1 along line C-C′, in accordance with some embodiments of the present disclosure.

FIG. 2D is a cross-sectional view of the example semiconductor device of FIG. 1 along line D-D′, in accordance with some embodiments of the present disclosure.

FIG. 2E is a cross-sectional view of the example semiconductor device of FIG. 1 along line E-E′, in accordance with some embodiments of the present disclosure.

FIGS. 3A and 3B collectively illustrates a flow chart of an example method for making the example semiconductor device of FIGS. 1-2E, in accordance with some embodiments of the present disclosure.

FIGS. 4A, 5A, 6A, 7A, 8A, 9A, 10A, 11A, 12, and 13 are cross-sectional views of a portion of the example semiconductor device along line A-A′ of FIG. 1 at intermediate stages of the method of FIGS. 3A and 3B, in accordance with some embodiments of the present disclosure.

FIGS. 4B, 5B, 6B, 7B, 8B, 9B, 10B, and 11B are cross-sectional views of a portion of the example semiconductor device along line B-B′ of FIG. 1 at intermediate stages of the method of FIGS. 3A and 3B, in accordance with some embodiments of the present disclosure.

FIGS. 4C, 5C, 6C, 7C, 8C, 9C, 10C, and 11C are cross-sectional views of a portion of the example semiconductor device along line C-C′ of FIG. 1 at intermediate stages of the method of FIGS. 3A and 3B, in accordance with some embodiments of the present disclosure.

FIGS. 4D, 5D, 6D, 7D, 8D, 9D, 10D, and 11D are cross-sectional views of a portion of the example semiconductor device along line D-D′ of FIG. 1 at intermediate stages of the method of FIGS. 3A and 3B, in accordance with some embodiments of the present disclosure.

FIGS. 4E and 11E are cross-sectional views of a portion of the example semiconductor device along line E-E′ of FIG. 1 at intermediate stages of the method of FIGS. 3A and 3B, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

Embodiments of the present disclosure provide a semiconductor qubit device having two semiconductor substrates coupled in a back-to-back configuration (i.e., a double-sided configuration), where a frontside of each semiconductor substrate includes an array of quantum dot qubit regions (or qubit regions) extending in a lateral direction. The qubit is configured for the control and readout of a spin of a single carrier (electron or hole) in the semiconductor substrate. Each of the qubit regions is defined in a channel region of the semiconductor substrate and traversed by a plunger gate disposed adjacent to a barrier gate. The semiconductor qubit device further includes a doped well separating backsides of the semiconductor substrates. By applying a voltage to the doped well, a potential barrier between the arrays of quantum dot qubit regions along a vertical direction is increased, thereby providing improved electrostatic control and confinement between the carriers (electrons or holes) along the vertical direction. In some embodiments, a transistor formed in the semiconductor qubit device may be realized as a planar field-effect transistor (FETs), a multi-gate transistor, a FinFET, a nanosheet FET, or a gate-all-around FET.

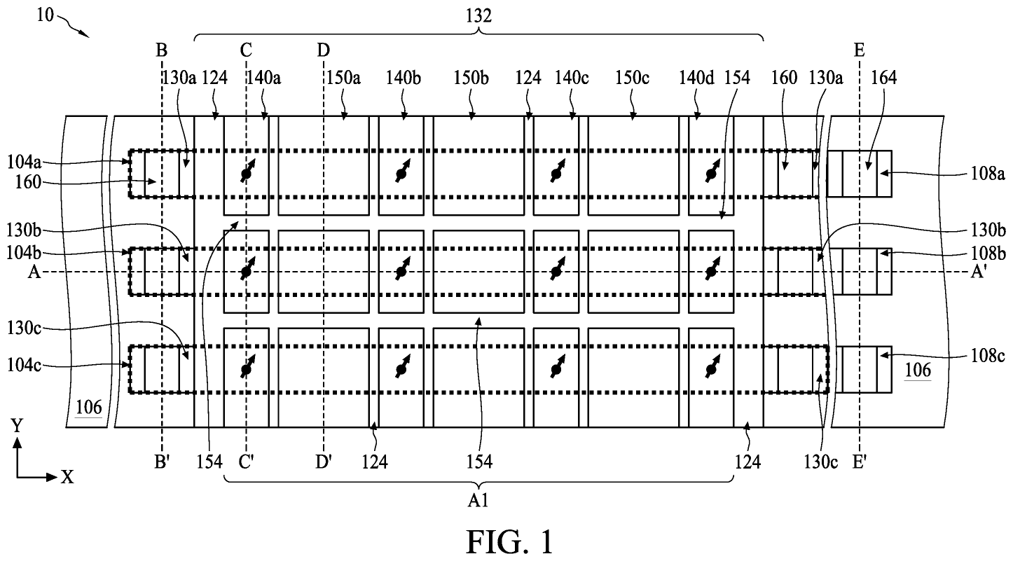

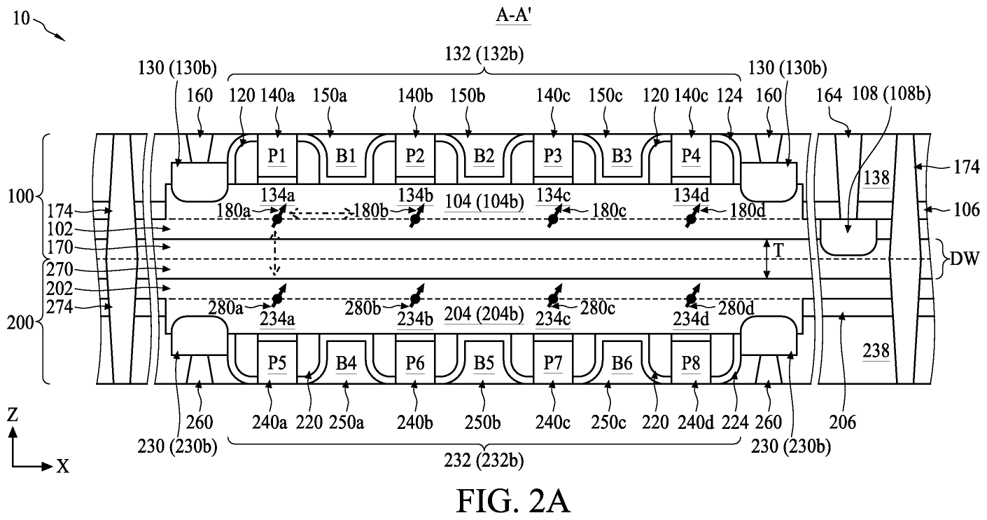

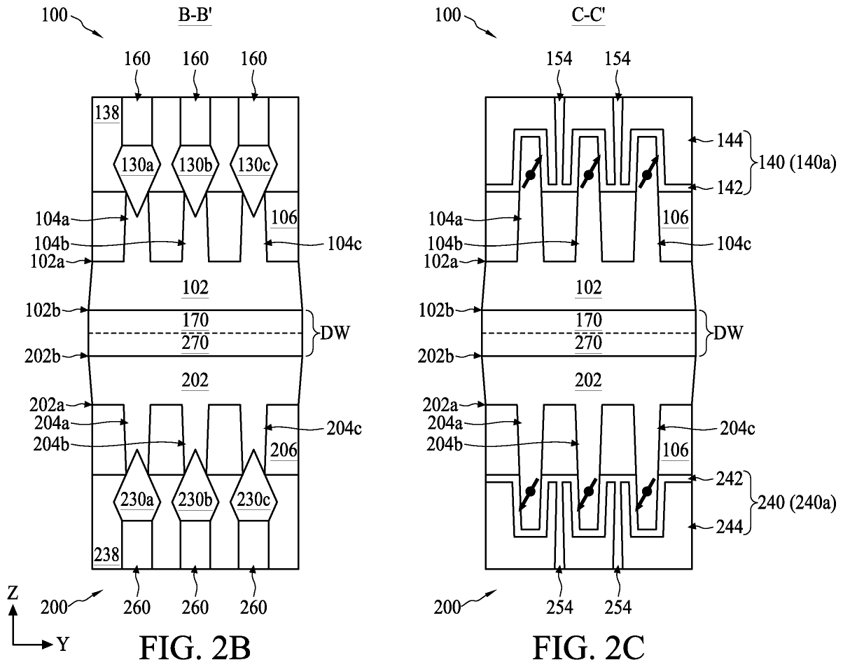

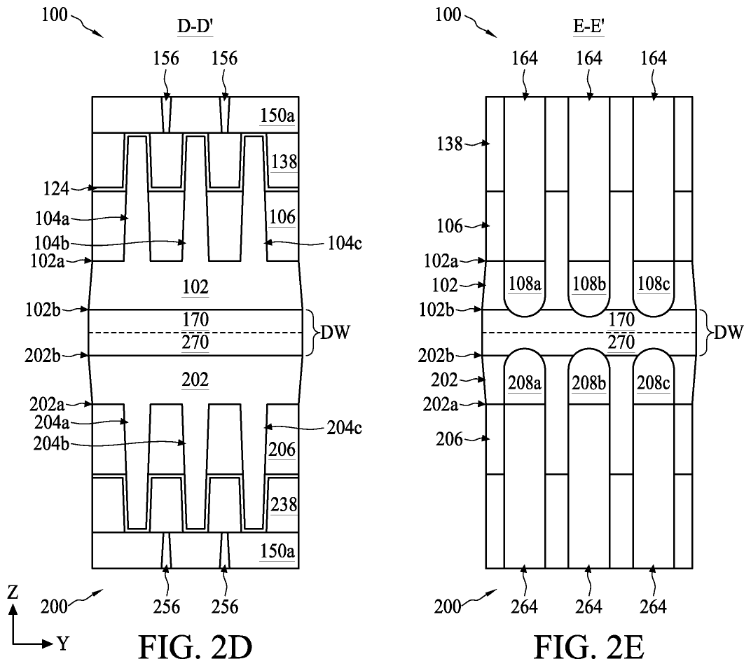

FIG. 1 is a top view of a device 10 in accordance with some embodiments of the present disclosure, FIG. 2A is a cross-sectional view of the device 10 of FIG. 1 along line A-A′, FIG. 2B is a cross-sectional view of the device 10 of FIG. 1 along line B-B′, FIG. 2C is a cross-sectional view of the device 10 of FIG. 1 along line C-C′, FIG. 2D is a cross-sectional view of the device 10 of FIG. 1 along line D-D′, and FIG. 2E is a cross-sectional view of the device 10 of FIG. 1 along line E-E′. Referring to FIGS. 2A-2E, the device 10 includes a top die (or a first die) 100 coupled to a bottom die (or a second die) 200, where a backside (e.g., a backside 102b of a substrate 102) of the top die 100 is bonded to a backside (e.g., a backside 202b of a substrate 202) of the bottom die 200.

A frontside (e.g., a frontside of the substrate 102 and a frontside of the substrate 202) of each of the top die 100 and the bottom die 200 includes a lateral, two-dimensional (e.g., along the XY plane as depicted in FIG. 1) array Al of quantum dots each defining a qubit (“quantum bit”) region in a channel region of an FET. Each qubit region is defined by a portion of the channel region traversed by a plunger gate structure (e.g., plunger gate structure 140) and is between two adjacent barrier gate structures (e.g., barrier gate structures 150). In the present embodiments, confinement of a carrier (e.g., an electron), by way of physical boundary and electrostatic control, is realized along both a lateral direction (e.g., the X axis) and a vertical direction (e.g., the Z axis), resulting in improved entanglement between laterally adjacent and vertically adjacent quantum dots. Together, the coupling of the top die 100 to the bottom die 200 in the back-to-back configuration allows parallel arrays of quantum dots to become entangled along an additional, i.e., the vertical, direction. It should be understood that the number of each type of features in the device 10 (e.g., active regions, gate structures, contacts, etc.) depicted in the present disclosure is for illustration purposes only and is not intended to limit the structure of the device 10 as such.

Referring to FIGS. 1-2E, collectively, the top die 100 includes the substrate 102 having the frontside 102a and the backside 102b opposite the frontside 102a along the Z axis. The top die 100 at the frontside 102a includes a plurality of active regions 104a-104c (collectively referred to as the active regions 104) and isolation regions 106 surrounding a bottom portion of each active region 104. In some embodiments, the active regions 104 are configured as three-dimensional fin structures extending vertically along the Z axis from the substrate 102 and laterally in a lengthwise direction along the X axis. As such, the resulting FET(s) formed from the active regions 104a-104c may be referred to as FinFETs. Alternatively, the active regions 104a-104c may be configured as planar structures extending over the substrate 102 in the XY plane, and the resulting FET(s) formed from the active regions 104a-104c may be referred to as planar FETs. In the present disclosure, the active regions 104a-104c are depicted to be fin structures and are hereafter referred to as fins 104a-104c. Referring to FIG. 1, the fins 104a-104c extend lengthwise along the X axis and are spaced from one another along the Y axis. In the present embodiments, the top die 100 at the backside 102b includes a doped well (e.g., a second doped well 170 as discussed in detail below) embedded therein (or otherwise formed thereover).

The substrate 102 includes a semiconductor substrate (or semiconductor layer), such as a bulk semiconductor, a semiconductor-on-insulator (SOI) substrate, or the like, which may be doped (e.g., with a P-type or an N-type dopant) or undoped. The substrate 102 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 102 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GalnP, and/or GalnAsP; or combinations thereof. In some embodiments, the substrate 102 includes a p-type silicon substrate (p-substrate). For example, p-type dopants are introduced into the substrate 102 to form the p-substrate.

In some embodiments, the isolation regions 106 include shallow trench isolation (STI) features having a recessed top surface such that upper portions of the fins 104 protrude from between neighboring portions of the isolation regions 106. The isolation regions 106 may include an oxide, such as silicon oxide (SiO and/or SiO₂), a nitride, a low-k (e.g., having a dielectric constant less than that of silicon oxide, which is about 3.9) dielectric material (e.g., phosphosilicate glass (PSG), borosilicate glass (BSG), boron-doped phosphosilicate glass (BPSG), undoped silicate glass (USG), etc.), the like, or combinations thereof.

Referring to FIGS. 1, 2A, and 2E, the substrate 102 at the frontside 102a includes a plurality of first doped wells 108a-108c (collectively referred to as the first doped well 108) each embedded in the substrate 102 (e.g., below the isolation regions 106) and disposed adjacent to a respective fins (e.g., adjacent to one of the source/drain features disposed over the fin) 104a-104c along the X axis. The first doped well 108 includes a top surface (over the frontside 102a) coupled to (e.g., in physical or electrical contact with) a doped well contact 164. The first doped well 108 further includes a bottom surface (facing the backside 102b) coupled to the second doped well 170 disposed on the backside 102b of the substrate 102. As such, by applying a voltage to the first doped well 108 through the doped well contact 164, the electric field of the second doped well 170 can be adjusted to generate or otherwise influence a potential barrier between, and thus the electrostatic control of, a quantum dot in the top die 100 and a corresponding quantum dot in the bottom die 200 along the Z axis.

The first doped well 108 includes a suitable dopant determined based on the type of carriers (e.g., electrons or holes) present in the qubit regions 134 provided in the top die 100. Furthermore, the first doped well 108 and the second doped well 170 include dopants of the same conductivity type. For embodiments in which the carriers include electrons, the first doped well 108 and the second doped well 170 both include a p-type dopant to provide the potential barrier between two electrons of the parallel arrays of quantum dots along the Z axis. In this regard, both the first doped swell 108 and the second doped well 170 are p-wells. Example p-type dopants include boron (B), gallium (Ga), indium (In), the like, or combinations thereof. Conversely, for embodiments in which the carriers include holes, the first doped well 108 and the second doped well 170 both include an n-type dopant. Example n-type dopants include phosphorous (P), arsenic (As), the like, or combinations thereof. In some embodiments, dopant concentration of the first doped well 108 is substantially the same as that of the second doped well 170. In some examples, the dopant concentration of first doped well 108 and the second doped well 170 may each be about 1×10¹⁸ cm⁻¹ to about 1×10¹⁹ cm⁻¹.

The doped well contact 164 may include a metal fill layer containing any suitable metal, such as tungsten (W), copper (Cu), ruthenium (Ru), aluminum (Al), gold (Au), cobalt (Co), the like, or combinations thereof. In some embodiments, the doped well contact 164 further includes a barrier layer (not depicted) disposed between the first doped well 108 and the metal fill layer. The barrier layer may include any suitable material, such as titanium (Ti), tantalum (Ta), titanium nitride (TiN), tantalum nitride (TaN), the like, or combinations thereof.

Referring to FIGS. 1, 2A, and 2B, each of the fins 104a-104c includes a pair of source/drain (S/D) features (or S/D regions) 130a-130c (collectively referred to as the S/D features 103), respectively, where the S/D features 130a are disposed over (or in) the fin 104a, the S/D features 130b are disposed over (or in) the fin 104b, and the S/D features 130c are disposed over (or in) the fin 104c. At least a bottom portion of each S/D feature 130 may be embedded in the corresponding fin 104 while a top portion of the S/D feature 130 may protrude from a top surface of the fin 104, as depicted herein. For a planar FET the top portion of the S/D feature 130 is substantially coplanar with a top surface of the substrate 102. A portion of each of the fins 104a-104c interposed between each pair of S/D features 130a-130c along the X axis is defined as a channel region 132a-132c (collectively referred to as the channel region 132), respectively. In the present embodiments, each channel region 132 defines a qubit region of the device 10 within which the quantum dots are provided.

In some embodiments, the substrate 102 and the channel region 132 are both of a first conductivity type, and the S/D features 130 are of a second conductivity type different from the first conductivity type. In some embodiments, the substrate 102 is a p-type silicon substrate (p-substrate), the channel region 132 is of p-type, and the S/D features 130 are of n-type, resulting in an n-type FET. In some embodiments, both the substrate 102 and the channel region 132 are of n-type, and the S/D features 130 are of p-type, resulting in a p-type FET.

In some embodiments, the top die 100 includes a plurality of S/D contacts 160 each coupled to a S/D feature 130. The S/D contacts 160 may each include a metal fill layer having a composition similar to that of the doped well contact 164 described above. In some embodiments, each S/D contact 160 further includes a barrier layer (not depicted) disposed between the S/D feature 130 and the metal fill layer, where the barrier layer may have a composition similar to the barrier layer of the doped well contact 164. In some embodiments, the top die 100 further includes a silicide layer (not depicted) disposed between each S/D contact 160 and the S/D feature 130.

Referring to FIGS. 1, 2A, and 2C, the top die 100 includes a plurality of plunger gate structures 140a, 140b, 140c, and 140d (collectively referred to as the plunger gate structures 140) disposed over the channel region 132 of each of the fins 104a-104c. The plunger gate structures (or plunger gates) 140 extending lengthwise along the Y axis (i.e., perpendicular to the fins 104) and are spaced from one another along the X axis. Each plunger gate structure 140 includes a plunger gate dielectric layer 142 and a plunger gate electrode 144 disposed over the plunger gate dielectric layer 142, where the plunger gate dielectric layer 142 traverses a portion of the channel region 132. In the depicted embodiments, two outermost plunger gate structures 140 along the X axis are each separated from an adjacent S/D feature 130 by a corresponding gate spacer 120. In some embodiments, an interfacial layer (not depicted) may be formed between the plunger gate dielectric layer 142 and the channel region 132 and may include an oxide, such as silicon oxide.

The plunger gate dielectric layer 142 may include any suitable dielectric material, such as silicon oxide, silicon nitride, a high-k dielectric material (i.e., having a dielectric constant greater than that of silicon oxide, which is about 3.9), the like, or combinations thereof. The high-k dielectric material may include an oxide or a silicate of Hf, Al, Zr, La, Mg, Ba, Ti, Pb, the like, or combinations thereof. The plunger gate electrode 144 may include any suitable metal, such as tungsten (W), copper (Cu), ruthenium (Ru), aluminum (Al), gold (Au), cobalt (Co), the like, or combinations thereof.

Referring to FIG. 2A, the top die 100 further includes the gate spacers 120 disposed along sidewalls of each plunger gate structure 140. The gate spacers 120 may include one or more layers of a suitable dielectric material, such as silicon nitride, silicon oxynitride, silicon carbonitride, a low-k material described above, the like, or combinations thereof.

Referring to FIGS. 1, 2A, and 2D, the top die 100 further includes a plurality of barrier gate structures 150a, 150b, and 150c (collectively referred to as the barrier gate structures 150) each interposed between two adjacent plunger gate structures 140 along the X axis. In this regard, each qubit region 134 (e.g., qubit regions 134a, 134b, 134c, and 124d corresponding to the plunger gate structures 140a, 140b, 140c, and 140d, respectively) is defined as a portion of the channel region 132 between two adjacent barrier gate structures (or barrier gates) 150, i.e., a portion of the channel region 132 traversed by each plunger gate structure 140. In the present embodiments, each of the carriers (e.g., electrons or holes) 180a, 180b, 180c, and 180d (collectively referred to as the carriers 180) is confined in the qubit region 134 of a corresponding quantum dot of the channel region 132. In some embodiments, by adjusting a voltage (i.e., potential) applied to two adjacent barrier gate structures 150 along the X axis, each qubit region 134 interposed between the barrier gate structures 150 allows only a single carrier (e.g., an electron or a hole) to pass from an entrance of the qubit region 134 (i.e., a portion of the channel region 132 traversed by a first one of the barrier gate structures 150) to an exit of the qubit region 134 (i.e., a portion of the channel region 132 traversed by a second one of the barrier gate structures 150) before allowing another carrier to enter into the qubit region 134.

In some embodiments, the top die 100 includes a dielectric layer 124 separating each barrier gate structure 150 from the channel region 132 and from the adjacent gate spacers 120. The dielectric layer 124 may include any suitable dielectric material, such as an oxide (e.g., silicon oxide, a metal oxide, etc.), a nitride (e.g., silicon nitride), a silicide (e.g., a metal silicide), the like, or combinations thereof. In some embodiments, the dielectric layer 124 has a composition different from that of the gate spacers 120. In the present embodiments, a top surface of the dielectric layer 124, a top surface of the barrier gate structure 150 over the dielectric layer 124, and a top surface of the adjacent plunger gate structures 140 are formed to be coplanar, or substantially coplanar.

Referring to FIGS. 2A, 2B, 2D, and 2E, the top die 100 further includes an interlayer dielectric (ILD) layer 138 disposed over the S/D features 130, where the ILD layer 138 provides isolation between the contact features (e.g., between one of the S/D contacts 160 and the doped well contact 164) and between one of the contact features and an adjacent gate structure (e.g., between one of the S/D contacts 160 and one of the outermost plunger gate structures 140). The ILD layer 138 may include an oxide, such as silicon oxide (SiO and/or SiO₂), a nitride, a low-k dielectric material described above, the like, or combinations thereof. In some embodiments, the ILD layer 138 includes silicon oxide. In some embodiments, to achieve etching selectivity, the ILD layer 138 and the dielectric layer 124 have different compositions. It is noted that, for purposes of illustrating various device features of the device 10, the ILD layer 138 is omitted in FIG. 1.

Though not depicted herein, the device 10 may further include additional contact features (e.g., gate contacts coupled to the plunger gate structures 140 and the barrier gate structures 150) and a plurality of interconnect structures coupled to the contact features over the frontside 102a. The interconnect structures may include horizontal interconnect structures (e.g., conductive lines) extending laterally over the substrate 102 and vertical interconnect structures (e.g., vias) configured to couple the horizontal interconnect structures along a vertical direction (e.g., the Z axis). The interconnect structures may be disposed in various intermetal dielectric (IMD) layers stacked along the vertical direction to form frontside multi-layer interconnect (MLI) structures (alternatively referred to as back-end-of-line, or BEOL, structures of the top die 100) that is coupled to front-end-of-line (FEOL) features as depicted herein through the various contact features (alternatively referred to as middle-end-of-line, or MEOL, structures of the top die 100). The MLI structures may be further coupled to frontside power rails configured to provide voltage to the FEOL features (e.g., the plunger gate structures 140, the barrier gate structures 150, the S/D features 130, the first doped well 108, etc.). In some embodiments, the interconnect structures may each have a composition similar to that of the doped well contact 164, and the IMD layers may each have the same composition as the ILD layer 138.

Moreover, in some embodiments, the top die 100 includes one or more through-substrate vias (or through-silicon vias; TSVs) 174 extending through the substrate 102, which includes the second doped well 170 at the backside 102b. In the depicted embodiments, the TSVs 174 are formed adjacent to the fin (i.e., active region) 104 and/or the first doped well 108 along the X direction. In the present embodiments, each TSV 174 is configured to couple conductive features disposed over the frontside 102a of the top die 100, such as the BEOL structures, to those disposed over the frontside 202a of the bottom die 200 through TSVs (e.g., TSVs 274) formed in the substrate (e.g., the substrate 202) of the bottom die 200. Each TSV 174 may include any suitable conductive material and may have a composition similar to that of the doped well contact 164.

Still referring to FIGS. 1-2E, the bottom die 200 includes features corresponding to those of the top die 100. For example, the bottom die 200 includes a substrate 202. The substrate 202 includes the frontside 202a and the backside 202b opposite the frontside 202a along the Z axis, where the backside 202b includes a third doped well 270 embedded therein (or otherwise formed thereover). The bottom die 200 includes a plurality of fins 204a-204c (collectively referred to as the fins 204) over the frontside 202a of the substrate 202, and isolation regions 206 surrounding bottom portions of the fins 204.

Each of the fins 204a, 204b, and 204c includes a pair of S/D features (or S/D regions) 230a, 230b, and 230c (collectively referred to as the S/D features 230) disposed thereover, respectively. A portion of each of the fins 204a-204c interposed between each pair of S/D features 230a-230c along the X axis is defined as a channel region 232a-232c (collectively referred to as the channel region 232), respectively. In some embodiments, the substrate 202 and the channel region 232 are both of a first conductivity type, and the S/D features 230 are of a second conductivity type different from the first conductivity type. The bottom die 200 further includes a plurality of S/D contacts 260 each coupled to an S/D feature 230.

Over each channel region 232, the bottom die 200 includes a plurality of plunger gate structures 240a, 240b, 240c, and 240d (collectively referred to as the plunger gate structures 240). Each plunger gate structure 240 includes a plunger gate dielectric layer 242 and a plunger gate electrode 244 disposed over the plunger gate dielectric layer 242, where the plunger gate dielectric layer 242 traverses a portion of the channel region 232. The bottom die 200 further includes gate spacers 220 disposed along sidewalls of each plunger gate structure 240. In the depicted embodiments, two outermost plunger gate structures 240 are each separated from an adjacent S/D feature 230 by the corresponding gate spacer 220.

The bottom die 200 further includes a plurality of barrier gate structures 250a, 250b, and 250c (collectively referred to as the barrier gate structures 250) each interposed between two adjacent plunger gate structures 240 along the X axis. In this regard, a qubit region 234 (e.g., qubit regions 234a, 234b, 234c, and 224d corresponding to the plunger gate structures 240a, 240b, 240c, and 240d, respectively) is defined as a portion of the channel region 232 between two adjacent barrier gate structures 250, i.e., a portion of the channel region 232 traversed by each plunger gate structure 240. In the present embodiments, each one of a plurality of carriers (e.g., electrons or holes) 280a, 280b, 280c, and 280d (collectively referred to as the carriers 280) is confined in the qubit region 234 of a corresponding quantum dot of the channel region 232.

In the present embodiments, the bottom die 200 further includes a dielectric layer 224 separating each barrier gate structure 250 from the channel region 232 and from the adjacent gate spacers 220, and an ILD layer 238 disposed over the S/D features 230 to isolate the contact features (e.g., the S/D contacts 260) from any adjacent conductive features (e.g., the plunger gate structures 240). Similar to the top die 100, the bottom die 200 may further include additional contact features (e.g., gate contacts coupled to the plunger gate structures 240 and the barrier gate structures 250), as a part of MEOL structures, and a plurality of interconnect structures coupled to the contact features, as a part BEOL structures of the bottom die 200, over the frontside 202a. Still further, the bottom die 200 includes one or more TSVs 274 extending through the substrate 202 (including the third doped well 270), where each TSV 274 is configured to couple conductive features disposed over the frontside 202a of the bottom die 200, such as the BEOL structures of the bottom die 200, to those disposed over the frontside 102a of the top die 100.

The bottom die 200 at the backside 202b includes the third doped well 270 that is directly coupled, by way of a wafer bonding mechanism, for example, to the second doped well 170 to form a common doped well DW sandwiched between the frontside 102a and the frontside 202a. In this regard, both the second doped well 170 and the third doped well 270 are coupled to the first doped well 108 and can thus be controlled by a voltage applied to the first doped well 108. In the present embodiments, the first doped well 108, the second doped well 170, and the third doped well 270 all include dopant of the same conductivity type. Furthermore, concentrations of the dopant in the second doped well 170 and the third doped well 270 may be substantially the same, such that the common doped well DW has substantially uniform composition across its thickness T along the Z axis. If the carriers include electrons, then the third doped well 270 and the second doped well 170 both include a p-type dopant (i.e., both are p-wells) to provide the electrostatic barrier between two electrons across two parallel arrays of quantum dots along the Z axis. As depicted, the common doped well DW is interposed between the plurality of the qubit regions 134 and the plurality of the qubit regions 234 along the Z axis, allowing entanglement between carriers (e.g., the carrier 180 and the carrier 280) in two parallel arrays of quantum dots along the Z axis.

During operation of the top die 100, an external magnetic field (not depicted) is applied to the qubit region 134. A voltage is applied to the plunger gate structure 140, which turns on the channel region 132 and produces a current that flows from one of the S/D features 130, through the channel region 132, to the other one of the S/D features 130. For embodiments in which the carriers 180 include electrons, each of the carriers 180 in each qubit region assumes an electron spin according to a voltage applied to the plunger gate structure 140 over the qubit region. The barrier gate structures 150, which are alternately arranged with the plunger gate structures 140, are used to define a location of each qubit region 134 as described above and control the tunnel coupling or the confinement of the carrier 180 between laterally adjacent qubit regions 134. For example, adjusting the voltage applied to the barrier gate structures 150 can increase or decrease a potential barrier of (i.e., electrostatic control to) the passing of the carrier 180 through each qubit region 134. The controlled tunnel coupling that allows only a single electron (or hole) to pass through the qubit region 134 before allowing any other electron (or hole) to move into the same qubit region 134 is referred to as a qubit.

In the present embodiments, by adjusting the voltage applied to each of the plunger gate structures 140 and the barrier gate structures 150, electrostatic control and confinement of the quantum dots present in the channel region 132 can be achieved along the X direction, thereby allowing the carriers 180 in two laterally adjacent qubit regions 134 to become entangled (as indicated by a horizontal dashed line between the qubit region 134a and the qubit region 134b in FIG. 2A) and form a stable eigenstate. Operation mechanisms of the bottom die 200 are substantially similar those of the top die 100 described above and are therefore omitted for purposes of brevity.

The coupling (by wafer bonding, for example) of the bottom die 200 to the top die 100 merges the second doped well 170 with the third doped well 270 to form the common doped well DW between the first array of quantum dots 180 in the top die 100 and the second array of quantum dots 280 in the bottom die 200. Consequently, by applying a voltage to the second doped well 170 through the first doped well 108, in addition to applying the voltage to the barrier gate structures 150, the potential barrier between quantum dots of the first array and the second array along the Z axis, such as between the qubit regions 134a and 234a, can be adjusted in a manner similar to the adjustment of potential barrier between two laterally adjacent qubit regions 134, such as between the qubit regions 134a and 134b.

As such, the device 10 is configured to produce additional electrostatic control and confinement of the quantum dots in the two-dimensional array Al of in the top die 100 (each corresponding to a qubit region 134) or the two-dimensional array (not depicted) of quantum dots in the bottom die 200 (each corresponding to a qubit region 234) along the vertical direction (e.g., the Z axis). In this regard, each of the carriers 180 (e.g., the carrier 180a) in the top die 100 can become entangled with not only a laterally adjacent carrier 180 (e.g., the carrier 180b) but also with a vertically adjacent carrier 280 (e.g., the carrier 280a), where such vertical entanglement is indicated by a vertical dashed line between the qubit regions 134a and 234a in FIG. 2A, resulting in more stable eigenstates of the corresponding quantum dots.

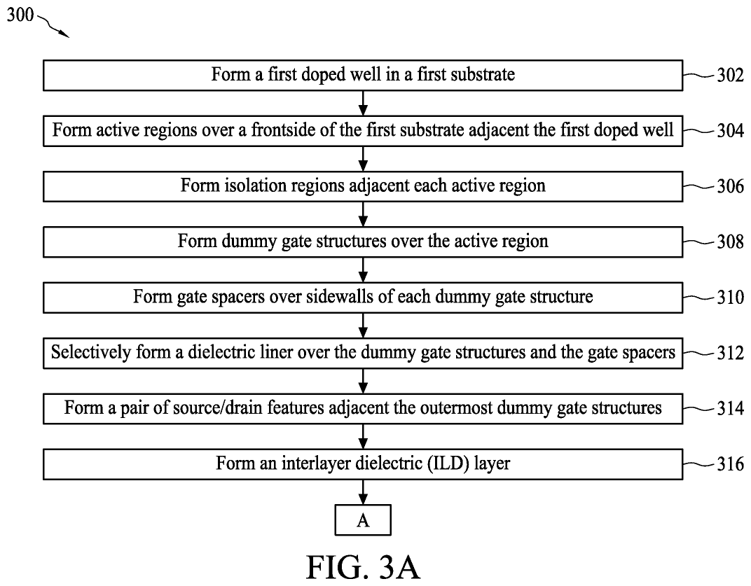

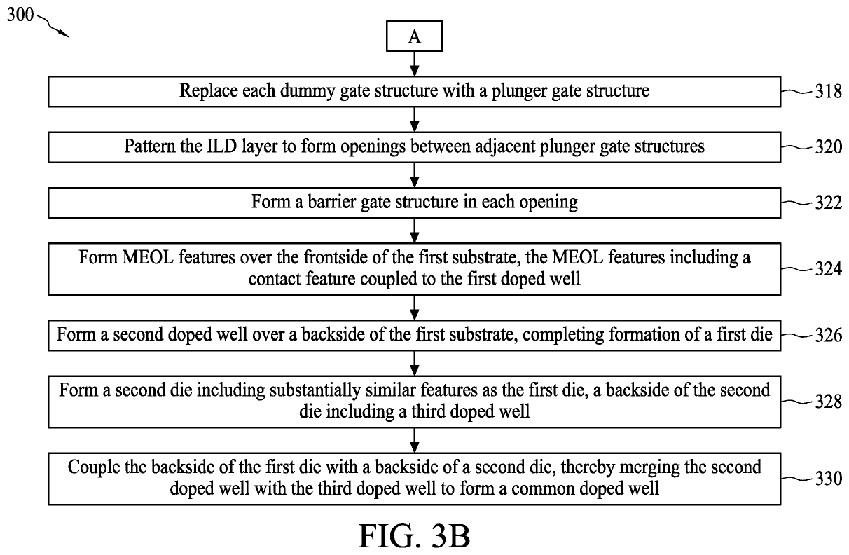

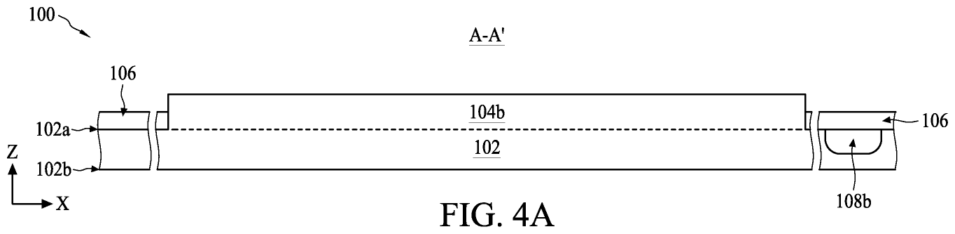

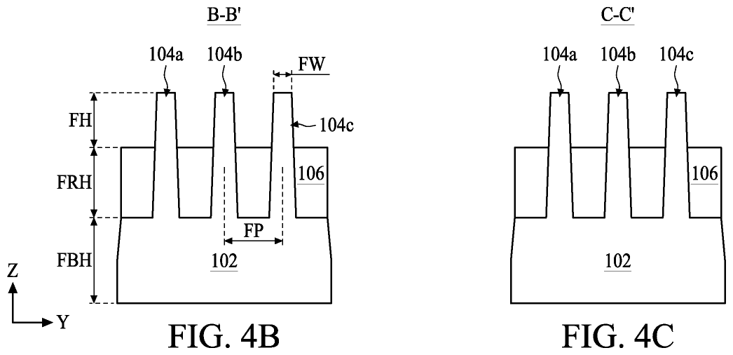

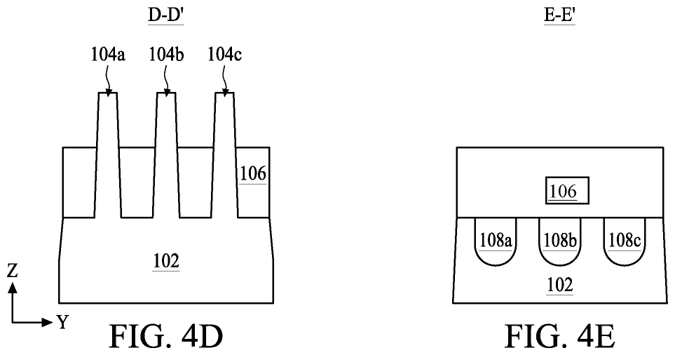

FIGS. 3A and 3B collectively illustrate a flowchart of a method 300 to form the device 10, according to one or more embodiments of the present disclosure. It is noted that the method 300 is merely an example and is therefore not intended to limit the present disclosure. Accordingly, additional operations may be provided before, during, and after the method 300 of FIGS. 3A and 3B, and that some other operations may only be briefly described herein. The order of the operations/processes may be interchangeable. In some embodiments, operations of the method 300 may be associated with cross-sectional views of the device 10 at various fabrication stages as shown in FIGS. 4A-13, which will be discussed in further detail below. Throughout the various views and illustrative embodiments, like reference numbers are used to designate like elements. Furthermore, embodiments of the device 10 are not limited to those depicted herein. For example, the device 10 may include a number of other devices such as inductors, fuses, capacitors, coils, etc., which are not shown herein for purposes of clarity.

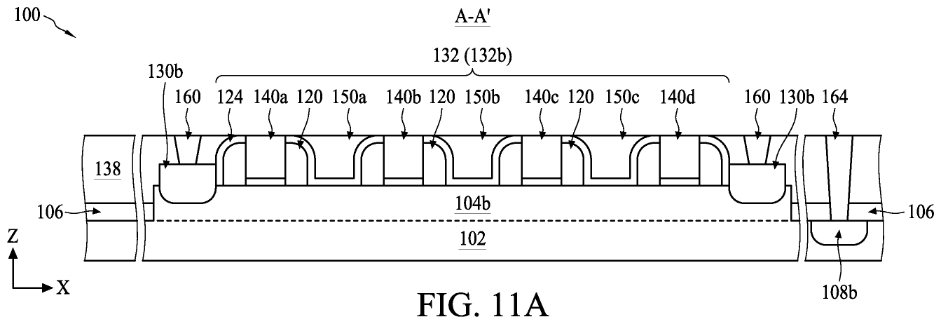

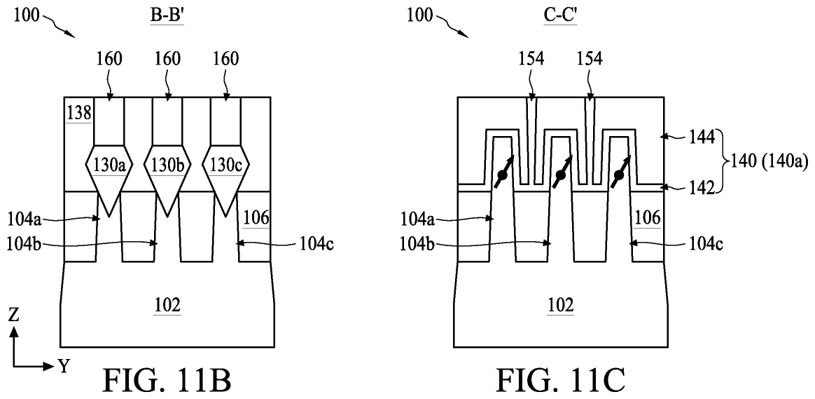

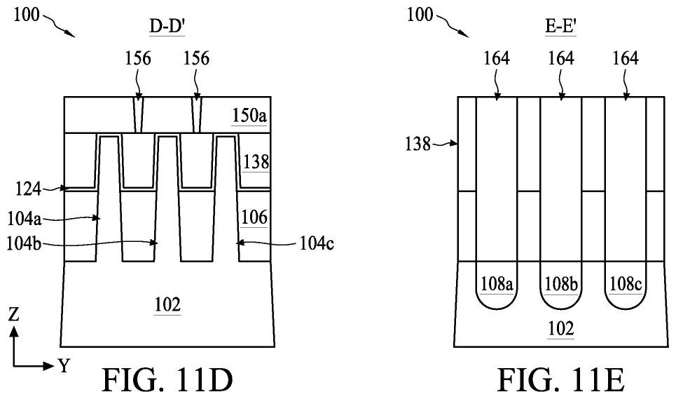

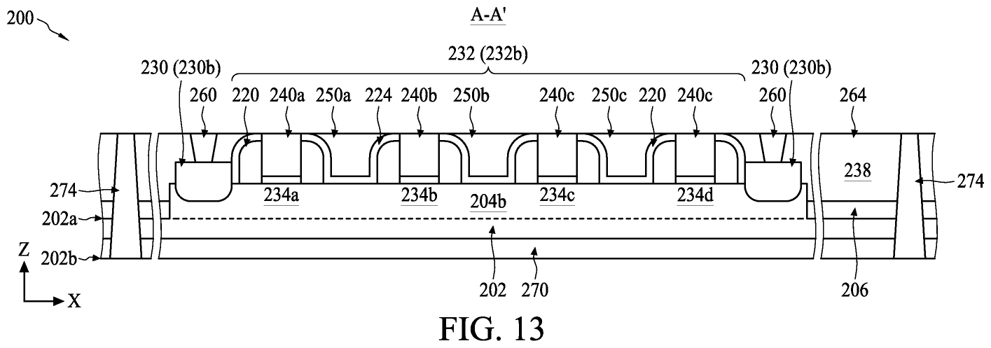

FIGS. 4A, 5A, 6A, 7A, 8A, 9A, 10A, 11A, and 12 are cross-sectional views of some embodiments of a portion (e.g., the top die 100) of the device 10 along the line A-A′ of FIG. 1 at intermediate stages of the method 300, in accordance with some embodiments of the present disclosure. FIG. 13 is a cross-sectional view of some embodiments of a portion (e.g., the bottom die 200) of the device 10 along the line A-A′ of FIG. 1 at intermediate stages of the method 300, in accordance with some embodiments of the present disclosure. FIGS. 4B, 5B, 6B, 7B, 8B, 9B, 10B, and 11B are cross-sectional views of some embodiments of a portion of the device 10 along the line B-B′ of FIG. 1 at intermediate stages of the method 300, in accordance with some embodiments of the present disclosure. FIGS. 4C, 5C, 6C, 7C, 8C, 9C, 10C, and 11C are cross-sectional views of some embodiments of the device 10 along the line C-C′ of FIG. 1 at intermediate stages of the method 300, in accordance with some embodiments of the present disclosure. FIGS. 4D, 5D, 6D, 7D, 8D, 9D, 10D, and 11D are cross-sectional views of some embodiments of the device 10 along the line D-D′ of FIG. 1 at intermediate stages of the method 300, in accordance with some embodiments of the present disclosure. FIGS. 4E and 11E are cross-sectional views of some embodiments of the device 10 along the line E-E′ of FIG. 1 at intermediate stages of the method 300, in accordance with some embodiments of the present disclosure.

Referring to FIGS. 3A and 4A-4E, the first doped well 108 (e.g., 108b as depicted) is formed in the substrate 102 at operation 302. The substrate 102 includes the frontside 102a opposite the backside 102b. In some embodiments, the substrate 102 includes a p-type silicon substrate (p-substrate). For example, p-type dopants are introduced into the substrate 102 to form the p-substrate.

In some embodiments, an implantation process is performed to introduce a first dopant into the substrate 102 to form the first doped well 108 over the frontside 102a of the substrate 102. The first dopant may be a p-type dopant or an n-type dopant, depending on the type of carriers passing through the qubit regions 134. For example, the first doped well 108 includes a p-type dopant for providing electrostatic control of electrons as carriers 180 in the qubit regions 134. In this regard, the first doped well 108 is a p-well formed in the p-substrate.

Referring to FIGS. 3A and 4A-4E, the fins (i.e., active regions) 104a-104c are formed over the frontside 102a adjacent a respective first doped well 108a-108c along the X axis at operation 304. The fins 104 protrude or extend vertically from the substrate 102 along the Z axis.

In some embodiments, the fins 104 are formed by patterning the substrate 102 using, for example, photolithography and etching techniques. For example, a mask layer (not depicted), including a pad oxide layer and an overlying pad nitride layer, is formed over the substrate 102.

The pad oxide layer may be a thin film comprising silicon oxide formed, for example, using a thermal oxidation process. The pad oxide layer may act as an adhesion layer between the substrate 102 and the overlying pad nitride layer. In some embodiments, the pad nitride layer is formed of silicon nitride, silicon oxynitride, silicon carbonitride, the like, or combinations thereof. The pad oxide layer and the pad nitride layer may each be formed using low-pressure chemical vapor deposition (LPCVD) or plasma enhanced-chemical vapor deposition (PECVD), for example.

The mask layer may be patterned using photolithography techniques. Generally, photolithography techniques utilize a photoresist material (not depicted) that is deposited, irradiated (or exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask, which is subsequently used to pattern exposed portions of the substrate 102 to form trenches (not depicted), thereby defining the fins 104 separated by the trenches. In some embodiments, the fins 104 are formed by etching trenches in the substrate 102 using, for example, reactive ion etch (RIE), neutral beam etch (NBE), the like, or combinations thereof. The etching may be anisotropically implemented. In some embodiments, the trenches may be strips (viewed from the top) parallel to each other, and closely spaced with respect to each other. In some embodiments, the trenches may be continuous and surround each fin 104. In this regard, though not depicted herein, a top surface of the resulting fins 104 is overlaid with the patterned mask until a subsequent fabrication step removes it.

In some embodiments, an implantation process is performed to dope the fins 104 such that the channel region 132 subsequently defined in each fin 104 includes a dopant suitable for the intended conductivity type of the resulting FET. For example, for an n-type FET, the fins 104 may be doped with a p-type dopant, and for a p-type FET, the fins 104 may be doped with an n-type dopant.

The fins 104 may be patterned by other suitable methods. In one example, the fins 104 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer (not depicted) is formed over the substrate 102 and patterned using a photolithography process. Spacers (not depicted) are formed alongside the patterned sacrificial layer using a self-aligned process. The sacrificial layer is then removed, and the remaining spacers, or mandrels, may then be used to pattern the fins 104.

In another example, a top portion of the substrate 102 may be replaced by or overlaid with a suitable material, such as an epitaxial material (not depicted) suitable for an intended conductivity type (e.g., n-type or p-type) of semiconductor devices to be formed. The epitaxial material may be grown over the substrate 102 by any suitable epitaxial process. Thereafter, the substrate 102, with the epitaxial material provided over the top portion, is patterned by a photolithography process described herein, for example, to form the fins 104 that include the epitaxial material.

In some examples, each fin 104 may be formed to a fin height FH, defined as a heigh of the fin 104 extending above the isolation regions 106, that ranges from approximately 0 nm (indicating a planar, rather than a fin, active region) to approximately 20 nm. Each fin 104 may be formed to a fin root height FRH, defined as a height of a portion of the fin 104 embedded in the isolation regions 106, that ranges from approximately 0 nm (indicating a planar, rather than a fin, active region) to approximately 20 nm. Each fin 104 may be formed to a fin base height, defined as a height of a portion of the substrate 102 below the fin 104, that ranges from approximately 0 nm indicating a planar, rather than a fin, active region) to approximately 20 nm. Each fin 104 may be formed to a fin width FW that ranges from approximately 5 nm to approximately 20 nm. Each fin 104 may be formed to a fin pitch FP that is greater than approximately 50 nm.

Still referring to FIGS. 3A and 4A-4E, the isolation regions 106 are formed over the substrate 102 to surround bottom portions of the fins 104 at operation 306. The isolation regions 106 may be formed by a high-density plasma chemical vapor deposition (HDPCVD), a flowable CVD (FCVD) (e.g., a CVD-based material deposition in a remote plasma system, followed by an annealing or curing process to densify the deposited material into another material, such as an oxide), spin coating, the like, or combinations thereof.

In some embodiments, the dielectric material of the isolation regions 106 include silicon oxide formed by a FCVD process. An annealing process may be performed once the dielectric material is deposited. A planarization process, such as a chemical-mechanical polish/planarization (CMP) process, may remove any excess dielectric material, such that a top surface of the dielectric material and a top surface of the fins 104 (or a top surface of the substrate 102 if the top die 100 includes a planar device) are substantially coplanar. The patterned mask over the top surface of the fins 104 may also be removed by the planarization process. Subsequently, the dielectric material is recessed to form the isolation regions 106 in the trenches each disposed between two adjacent fins 104. In some embodiments, the isolation regions 106 include shallow trench isolation (STI) features. The isolation regions 106 are recessed such that the upper portions of the fin 104 protrude from between neighboring isolation regions 106.

As another example of forming the fins 104 and the isolation regions 106, a dielectric layer (not depicted) may be formed over the top surface of the substrate 102; trenches may be etched through the dielectric layer; homoepitaxial structures may be epitaxially grown in the trenches; and the dielectric layer may be recessed such that the homoepitaxial structures protrude from the dielectric layer to form the fins 104. In yet another example, a dielectric layer (not depicted) may be formed over the top surface of the substrate 102; trenches may be etched through the dielectric layer; heteroepitaxial structures may be epitaxially grown in the trenches using a material different from the substrate 102; and the dielectric layer may be recessed such that the heteroepitaxial structures protrude from the dielectric layer to form the fins 104. The epitaxially grown material(s) or structures may be in situ doped during growth, which may obviate prior and subsequent implantations although in situ and implantation doping may be used together.

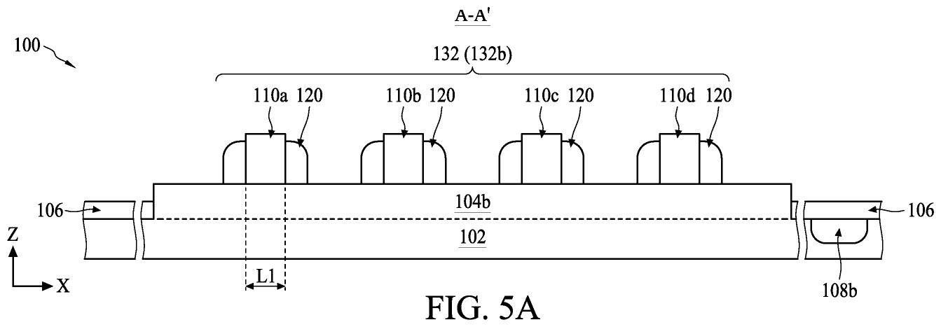

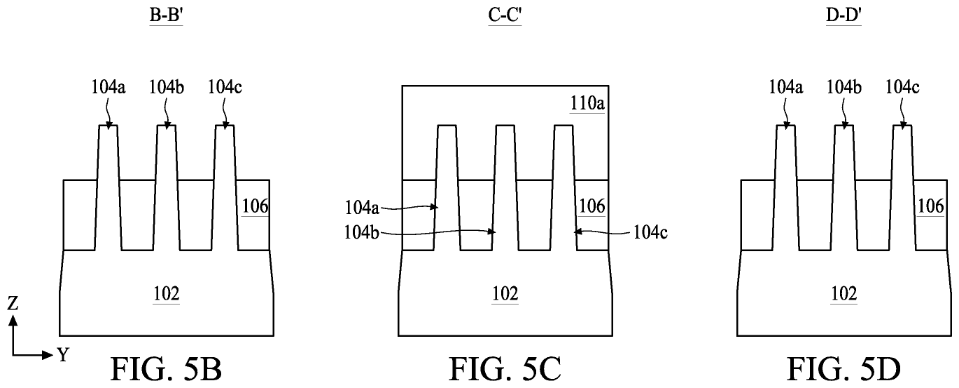

Referring to FIGS. 3A and 5A-5D, dummy gate structures 110a-110d (collectively referred to as the dummy gate structures 110) are formed over a portion of each fin 104 defined as the channel region 132 at operation 308. Each dummy gate structure 110 may include a dummy gate dielectric layer (not depicted separately) over the fins 104 and a dummy gate electrode (not depicted separately) over the dummy gate dielectric layer. The dummy gate structure 110 may optionally include an interfacial layer between the fins 104 and the dummy gate dielectric layer, where the interfacial layer may include an oxide, such as silicon oxide. The dummy gate dielectric layer may include any suitable dielectric material, such as silicon oxide, silicon nitride, multilayers thereof, or the like. The dummy gate electrode may include polysilicon. In some examples, each dummy gate structure 110 may be formed to a first gate length L1 that ranges from approximately 5 nm to approximately 20 nm.

Various layers of each dummy gate structure 110 may be sequentially deposited as blanket layers over the fins 104 by any suitable process, such as CVD, atomic layer deposition (ALD), or physical vapor deposition (PVD), thermally grown, or chemically grown, and then planarized by a CMP process, for example. A mask layer (not depicted) including silicon nitride or the like may be deposited over the various blanket layers of the dummy gate structure 110. The mask layer may be patterned using a series of photolithography and etching processes and then transferred to the blanket layers using any suitable etching processes to form the dummy gate structures 110.

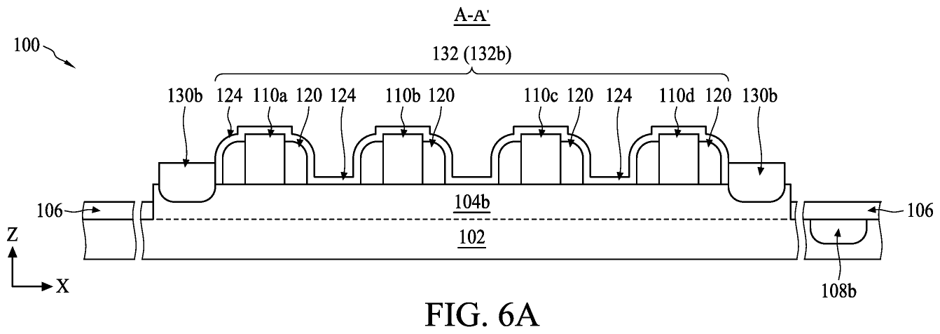

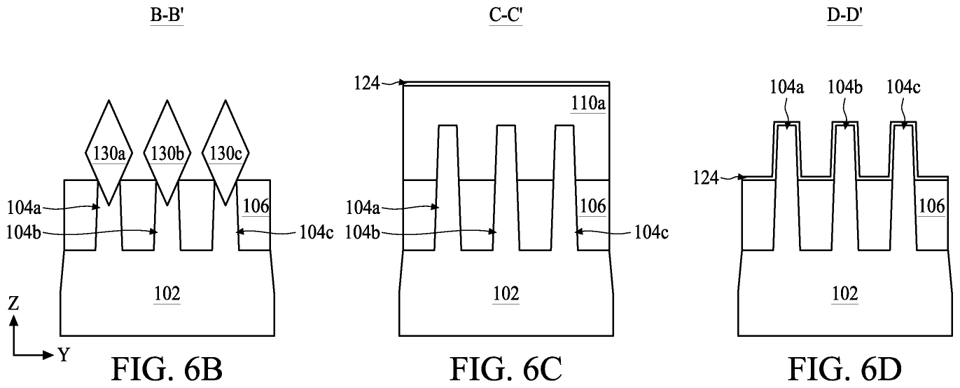

Referring to FIGS. 3A and 6A-6D, the gate spacers 120 are formed over sidewalls of each dummy gate structure 110 at operation 310. The gate spacers 120 are formed to surround (e.g., along and contacting the sidewalls of) each dummy gate structure 110. It should be understood that any number of gate spacers can be formed around the dummy gate structures 110 while remaining within the scope of the present disclosure.

The gate spacers 120 may be formed by first conformally depositing a dielectric layer over the dummy gate structures 110 using any suitable deposition process, such as thermal oxidation, CVD, or the like, and subsequently removing portions of the dielectric layer using a suitable etching process (e.g., a directional or anisotropic dry etching process), leaving the gate spacer 120 along opposite sidewalls of the dummy gate structures 110. In some embodiments, etching the dielectric layer removes topmost portions of the gate spacers 120, resulting in a rounded profile in the gate spacers 120 as depicted herein.

Referring to FIGS. 3A and 6A-6D, the dielectric layer 124 is selectively formed over the channel region 132 at operation 312. In the present embodiments, the dielectric layer 124 overlays each dummy gate structure 110, the gate spacers 120, and portions of the fin 104 interposed between the gate spacers 120 in the channel region 132. In some embodiments, the dielectric layer 124 is configured as a protective or masking layer over the channel region 132 during the subsequent formation of the S/D features 130.

The dielectric layer 124 may be formed by any suitable process. For example, the dielectric layer 124 may be first conformally deposited over the substrate 102 by any suitable process, such as CVD, ALD, or PVD. A patterned mask layer (e.g., a patterned photoresist layer; not depicted) may be formed over portions of the dielectric layer 124 over the channel region 132, and the remaining portions of the dielectric layer 124 exposed by the patterned mask layer may then be removed using any suitable etching processes, leaving behind the dielectric layer 124 over the channel region 132. The patterned mask layer may then be removed by any suitable process, such as plasma ashing or resist stripping.

Still referring to FIGS. 3A and 6A-6D, the pair of S/D features 130 are formed over the fin 104 at operation 314. The S/D features 130 are each disposed adjacent an outermost dummy gate structure 110 along the X axis.

In some embodiments, forming the S/D features 130 includes first removing portions of the fin 104 adjacent to the channel region 132 to form S/D recesses (not depicted). The S/D recesses may be formed by performing any suitable etching process, such as a dry etching process. For example, the S/D recesses may be formed by an anisotropic dry etching process using the dummy gate structures 110 (e.g., dummy gate structures 110 formed in an adjacent channel region 132 along the X axis that are not depicted herein) as an etching mask. A depth of the S/D recesses may be controlled by changing one or more parameters of the etching process. Subsequently, the S/D features 130, each including one or more doped epitaxial layers, are formed (or grown) in their respective S/D recesses by any suitable process, such as metal-organic CVD (MOCVD), molecular beam epitaxy (MBE), liquid phase epitaxy (LPE), vapor phase epitaxy (VPE), selective epitaxial growth (SEG), the like, or combinations thereof. Each pair of the S/D features 130 include one or more dopants corresponding to the conductivity type of the resulting FET. For example, the S/D features 130 may include a p-type dopant to form a p-type FET and, alternatively, the S/D features 130 may include an n-type dopant to form an n-type FET. In some embodiments, the S/D features 130 are doped with an n-type dopant to form an n-type FET over the substrate 102, which includes a p-substrate.

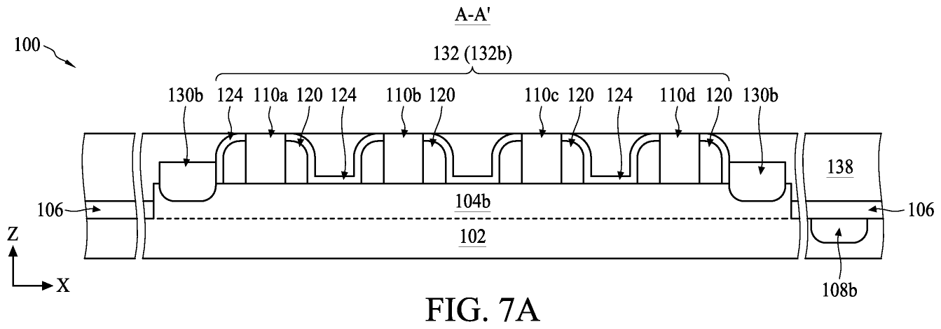

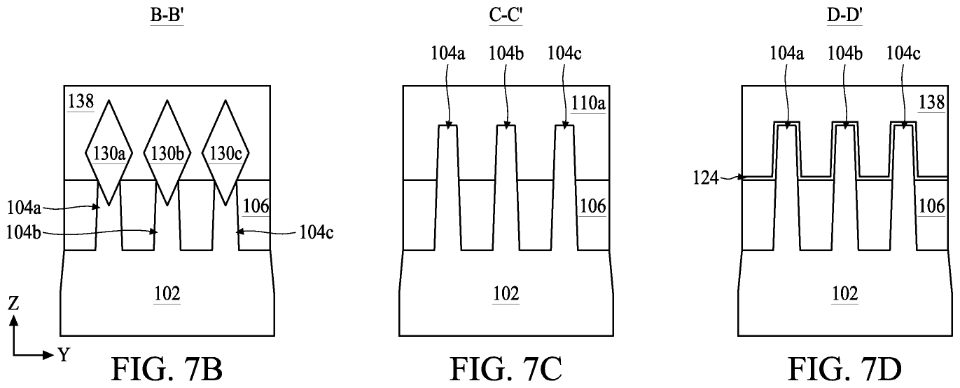

Referring to FIGS. 3A and 7A-7D, the ILD layer 138 is formed over the top die 100 at operation 316. In some embodiments, prior to forming the ILD layer 138, a contact etch stop layer (CESL; not depicted) is formed over the top die 100. The ILD layer 138 and CESL include different materials to provide etching selectivity therebetween in subsequent fabrication processes. The CESL may be formed by a suitable formation method such as CVD, ALD, PVD, the like, or combinations thereof. The ILD layer 138 may be deposited by any suitable method, such as CVD, PECVD, FCVD, or the like. After the ILD layer 138 is deposited, a planarization process, such as a CMP process, may be performed to achieve a substantially coplanar top surfaces for the ILD layer 138, the dummy gate structures 110, and the dielectric layer 124, for example.

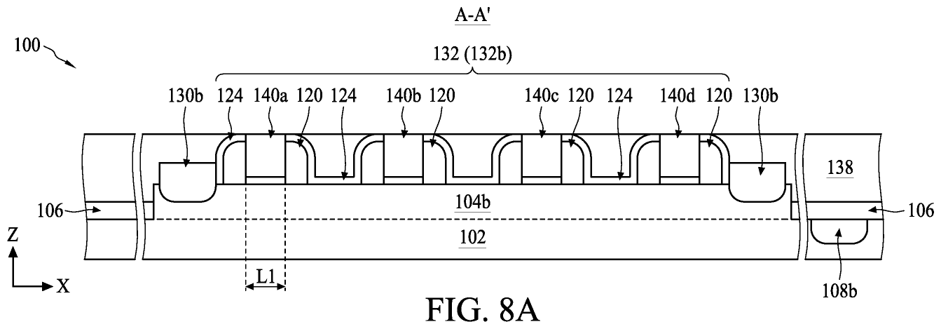

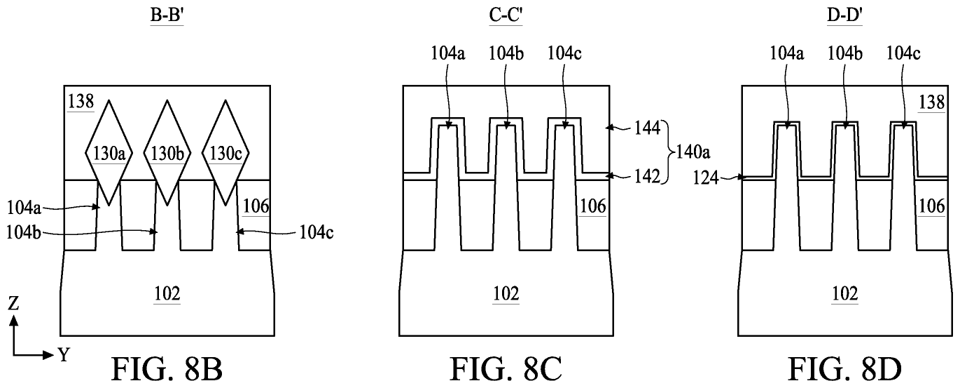

Referring to FIGS. 3B and 8A-8D, the dummy gate structures 110 are replaced with the plunger gate structures 140 between the gate spacers 120 at operation 318. Replacing the dummy gate structures 110 includes first removing the dummy gate structures 110 to form gate trenches (not depicted) between the gate spacers 120. In some embodiments, the dummy gate structures 110 are removed by one or more etching steps between the respective gate spacers 120 to expose portions of the channel region 132 corresponding to the qubit regions 134. In some embodiments, the dummy gate dielectric layer (not depicted) may be used as an etch stop layer when the dummy gate electrode is etched. The dummy gate dielectric layer may then be removed after the removal of the dummy gate electrode.

Subsequently, the plunger gate structures 140, each including at least the plunger gate dielectric layer 142 and the plunger gate electrode 144, are formed in the gate trenches. For example, the plunger gate dielectric layer 142 may be formed in the gate trenches by any suitable method, such as ALD, CVD, PECVD, molecular beam deposition (MBD), the like, or combinations thereof. The plunger gate electrode 144 may be formed by any suitable method, such as PVD, CVD, electroplating, electroless plating, the like, or combinations thereof, as a blanket layer over the plunger gate dielectric layer 142 and subsequently planarized by a CMP process, for example, to expose a top surface of the gate spacers 120. In some examples, each of the plunger gate structures 140 inherit the first gate length L1 of the dummy gate structure 110, which may range from approximately 5 nm to approximately 20 nm.

While not depicted, the plunger gate electrode 144 may further include a barrier layer, a seed layer, the like, or combinations thereof. In one example, the barrier layer may include Ti, Ta, TiN, TaN, the like, or combinations thereof, and may be deposited by any suitable method, such as CVD or ALD. In some embodiments, an interfacial layer (not depicted) may be formed in the gate trenches before forming the plunger gate dielectric layer 142. The interfacial layer may include an oxide, such as silicon oxide, and may be formed by any suitable method, such as ALD, CVD, thermal oxidation, chemical oxidation, the like, or combinations thereof.

In some embodiments, though not depicted, one or more work function layers may be formed conformally over the plunger gate dielectric layer 142 before forming the plunger gate electrode 144. The work function layers may include a p-type work function layer, an n-type work function layer, multi-layers thereof, or combinations thereof. In the discussion herein, a work function layer may also be referred to as a work function metal. Examples of the work function layers may include TiN, TaN, Ru, Mo, Al, ZrSi₂, MoSi₂, TaSi₂, NiSi₂, WN, Ti, Ag, TaAl, TaAIC, TiAIN, TaC, TaCN, TaSiN, Mn, Zr, the like, or combinations thereof. The work function layer(s) may be deposited by CVD, PVD, ALD, the like, or combinations thereof. Additional layers (not depicted) including a capping layer, a glue layer (or an adhesion layer), the like, or combinations thereof may also be formed between the plunger gate dielectric layer 142 and the plunger gate electrode 144 by any suitable method, such as CVD, PVD, ALD, MBD, the like, or combinations thereof.

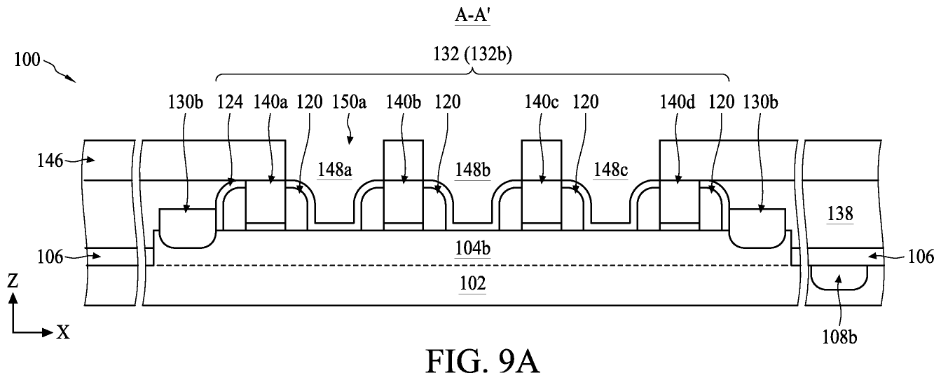

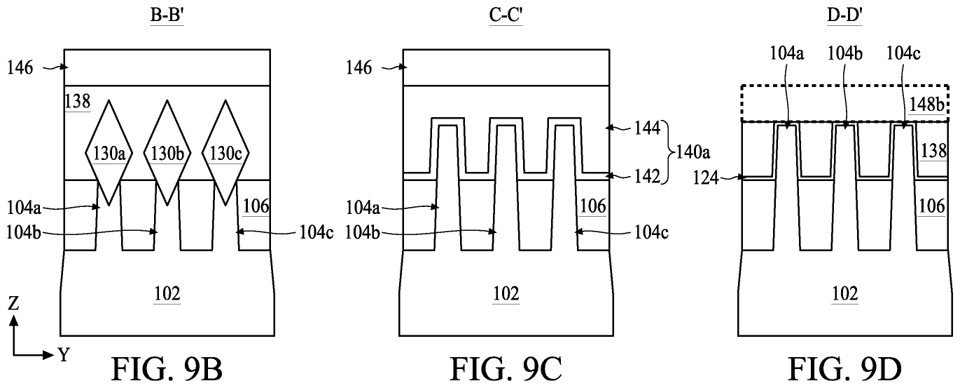

Referring to FIGS. 3B and 9A-9D, the ILD layer 138 is patterned to form openings 148a, 148b, and 148c (collectively referred to as the openings 148) interspersed between the plunger gate structures 140a-140d at operation 320. In some embodiments, the openings 148 are formed by first forming a patterned mask layer 146 over the ILD layer 138, where the patterned mask layer 146 may include a patternable material, such as a photoresist material, by a suitable method, such as a photolithography process described above. The patterned mask layer 146 includes a plurality of openings corresponding to portions of the ILD layer 138 to be removed, i.e., between two adjacent plunger gate structures 140, while portions of the ILD layer 138 over the plunger gate structures 140, the S/D features 130, the first doped well 108, etc., remain under the patterned mask layer 146. Subsequently, the exposed portions of the ILD layer 138 are removed by any suitable etching process, such as a dry etching process or a wet etching process, to form the openings 148. The resulting openings 148 each expose portions of the dielectric layer 124 between two adjacent plunger gate structures 140. Thereafter, the patterned mask layer 146 is removed by any suitable method, such as plasma ashing or resist stripping.

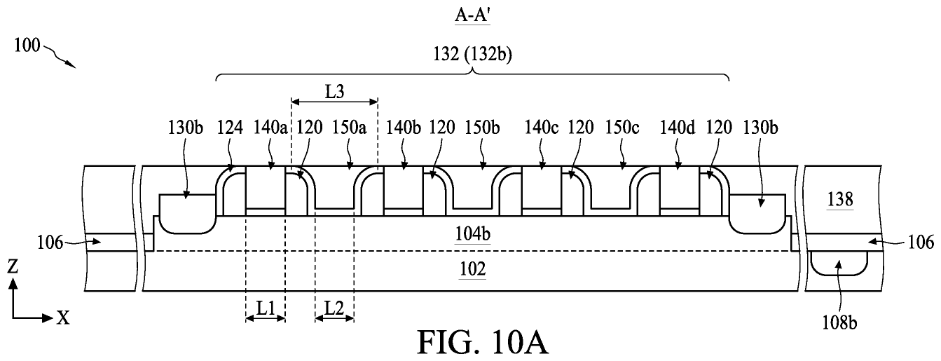

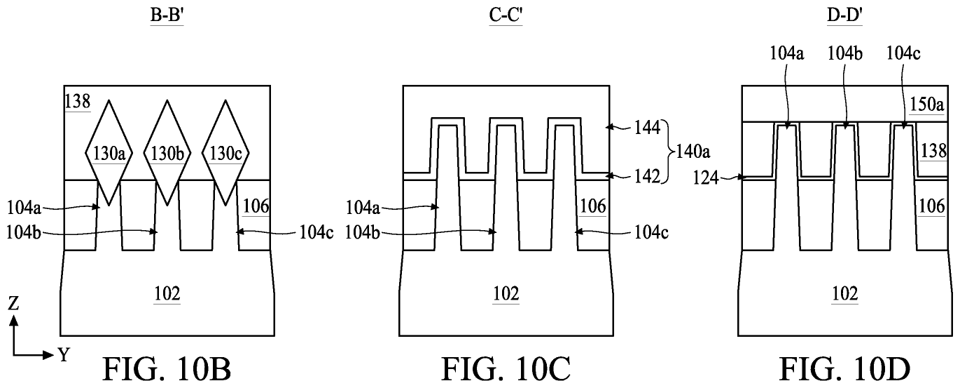

Referring to FIGS. 3B and 10A-10D, the barrier gate structures 150a-150c are each formed in the openings 148a-148c, respectively, at operation 322. In some embodiments, the barrier gate structures 150 are formed by forming a metal layer over the plunger gate structures 140, thereby filling the openings 148, and subsequently planarizing the metal layer to form the barrier gate structures 150 between two adjacent plunger gate structures 140. As described above, two adjacent barrier gate structures 150 define an entrance and an exit, respectively, of each qubit region 134 corresponding to each quantum dot. In some examples, a bottom portion of each barrier gate structure 150 may be formed to a second gate length L2 and a top portion of each barrier gate structure 150 may be formed to a third gate length L3 that is greater than the second gate length L2. Each of the second gate length L2 and the third gate length L3 may range from approximately 5 nm to approximately 20 nm.

Referring to FIGS. 3B and 11A-11E, various contact features (i.e., MEOL structures), such as the S/D contacts 160 and the doped well contact 164, are formed in the ILD layer 138 at operation 324. As described above, each S/D contact 160 is coupled to an S/D feature 130, while the doped well contact 164 is coupled to the first doped well 108 (and subsequently to the second doped well 170). In some embodiments, the ILD layer 138 is first patterned to form a plurality of contact openings (not depicted) to expose a corresponding feature (e.g., the S/D feature 130 or the first doped well 108) by a series of lithographic patterning and etching processes similar to those described above. In the case of the S/D contacts 160, the etching of the corresponding contact openings may be stopped on the S/D features 130 and/or the silicide layer (not depicted) formed over the S/D features 130. In the case of the doped well contact 164, the etching of the corresponding contact opening may be stopped on the first doped well 108. Subsequently, a metal fill layer described above is deposited over the top die 100, thereby filling each contact opening. A planarization process, such as a CMP process, is performed to remove portions of the metal fill layer formed over the ILD layer 138, resulting in the S/D contacts 160 and the doped well contact 164. In some embodiments, a barrier layer described above is formed in the contact openings before depositing the metal fill layer.

Additional contact features, such as gate contacts (not depicted) each coupled to a plunger gate structure 140 and gate contacts (not depicted) each coupled to a barrier gate structure 150, may also be formed at operation 324. Furthermore, the MLI structures (i.e., the BEOL structures; not depicted) described above may also be formed over and coupled to the contact features at operation 324.

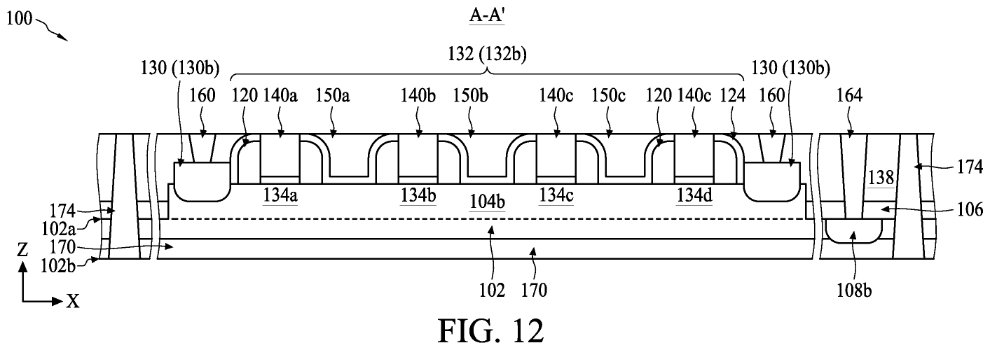

Referring to FIGS. 3B and 12, the second doped well 170 is formed over the backside 102b of the substrate 102 at operation 326, resulting in the top die 100. Before forming the second doped well 170, the top die 100 is inverted such that the backside 102b is exposed for processing. Subsequently, an implantation process is performed to dope at least a region of the backside 102b that corresponds to the channel region 132 of the top die 100. In some embodiments, parameters of the implantation process, such as doping energy, are tuned to ensure that the second doped well 170 is sufficiently thick to physically contact a bottom portion of the first doped well 108.

Referring to FIGS. 3B and 13 and at operation 328, the bottom (second) die 200 is formed subsequently to, or concurrently with, the top (first) die 100 by implementing operations 302 to 326. The bottom die 200 includes features that are substantially similar to those of the top die 100 as described above, with the exception that the bottom die 200 does not include any doped well contact similar to the doped well contact 164 of the top die 100.

Thereafter, as depicted in FIGS. 1-2E, the top die 100 is coupled or bonded to the bottom die 200 by merging the second doped well 170 with the third doped well 270 to form the common doped well DW in the device 10 at operation 330. The top die 100 may be coupled to the bottom die 200 by any suitable wafer bonding process. In some examples, the top die 100 and the bottom die 200 may be bonded by connection of a TSV 174 with a TSV 274, or other die-to-die connections including hybrid bonding via a bonding interface layer, solder bumps, the like, or combinations thereof. In some examples, referring to FIG. 2A, the thickness T of the DW ranges from approximately 5 nm to approximately 20 nm. By bonding the top die 100 and the bottom die 200 together, the channel regions 132 and the 232 are vertically aligned, such that entanglement between the carriers 180 and 280 along the Z axis can be realized in response to a voltage applied to the common doped well DW through the first doped well 108.

According to one aspect of the present disclosure, a semiconductor device includes a first substrate having a first frontside and a first backside separated along a first direction. The semiconductor device includes first source/drain features over the first frontside. The semiconductor device includes a first barrier gate over the first frontside between the first source/drain features. The semiconductor device includes a first plunger gate adjacent the first barrier gate along a second direction perpendicular to the first direction. The first plunger gate defines a first quantum bit region over the first frontside. The semiconductor device includes a second substrate having a second frontside and a second backside separated along the first direction. The semiconductor device includes second source/drain features over the second frontside. The semiconductor device includes a second barrier gate over the second frontside between the second source/drain features. The semiconductor device includes a second plunger gate adjacent the second barrier gate. The second plunger gate defines a second quantum bit region over the second frontside. The second quantum bit region is aligned with the first quantum bit region along the first direction. The semiconductor device includes a doped well extending between the first backside and the second backside along the first direction.

According to another aspect of the present disclosure, a semiconductor device includes a first substrate having a first side and a second side opposite the first side. The semiconductor device includes a second substrate having a third side and a fourth side opposite the third side. The semiconductor device includes a first doped well merging the second side with the fourth side. The semiconductor device includes a first channel region extending along a first direction over the first side. The semiconductor device includes first plunger gate structures and first barrier gate structures alternately arranged in the first channel region along the first direction. The first plunger gate structures each define a first quantum bit region. The semiconductor device includes a second channel region extending along the first direction over the third side. The semiconductor device includes second plunger gate structures and second barrier gate structures alternately arranged in the second channel region along the first direction. The second plunger gate structures each define a second quantum bit region. The semiconductor device includes a second doped well disposed in the first substrate and adjacent to one of the first plunger gate structures along the first direction. The second doped well is coupled to the first doped well.

According to yet another aspect of the present disclosure, a method includes forming first source/drain features over a frontside of a first substrate. The first substrate includes a backside opposite the frontside. The method includes forming first plunger gates between the first source/drain features. The first plunger gates each define a first quantum bit region over the frontside of the first substrate. The method includes forming first barrier gates each interposed between two adjacent first plunger gates. The method includes forming a first doped well over the backside of the first substrate. The method includes forming second source/drain features over a frontside of a second substrate. The second substrate includes a backside opposite the frontside. The method includes forming second plunger gates between the second source/drain features. The second plunger gates each define a second quantum bit region over the frontside of the second substrate. The method includes forming second barrier gates each interposed between two adjacent second plunger gates. The method includes forming a second doped well over the backside of the second substrate. The method includes merging the first doped well with the second doped well, thereby coupling the first substrate to the second substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first substrate having a first frontside and a first backside separated along a first direction;
first source/drain features over the first frontside;
a first barrier gate over the first frontside between the first source/drain features;
a first plunger gate adjacent the first barrier gate along a second direction perpendicular to the first direction, the first plunger gate defining a first quantum bit region over the first frontside;
a second substrate having a second frontside and a second backside separated along the first direction;
second source/drain features over the second frontside;
a second barrier gate over the second frontside between the second source/drain features;
a second plunger gate adjacent the second barrier gate, the second plunger gate defining a second quantum bit region over the second frontside, the second quantum bit region aligned with the first quantum bit region along the first direction; and
a doped well extending between the first backside and the second backside along the first direction.

2. The semiconductor device of claim 1, wherein the doped well includes a p-type dopant.

3. The semiconductor device of claim 1, wherein the doped well is a first doped well, the semiconductor device further comprising a second doped well spaced from one of the first source/drain features along the second direction, the second doped well coupled to the first doped well along the first direction.

4. The semiconductor device of claim 3, wherein the second doped well and the first doped well are of the same conductivity type.

5. The semiconductor device of claim 1, further comprising:
a first dielectric layer between the first barrier gate and the first substrate;
a second dielectric layer between the first plunger gate and the first substrate;
a third dielectric layer between the second barrier gate and the second substrate; and
a fourth dielectric layer between the second plunger gate and the second substrate.

6. The semiconductor device of claim 5, further comprising:
a pair of first gate spacers along sidewalls of the first plunger gate; and
a pair of second gate spacers along sidewalls of the second plunger gate.

7. The semiconductor device of claim 6, wherein the first dielectric layer is over the first gate spacers and the second dielectric layer is over the second gate spacers.

8. The semiconductor device of claim 1, further comprising:
a first through-substrate via (TSV) extending from the first frontside to the doped well along the first direction; and
a second TSV extending from the second frontside to the doped well along the first direction, the second TSV coupled to the first TSV.

9. The semiconductor device of claim 1, further comprising a third plunger gate adjacent the first barrier gate along the second direction, the third plunger gate defining a third quantum qubit region over the first frontside.

10. A semiconductor device, comprising:
a first substrate having a first side and a second side opposite the first side;
a second substrate having a third side and a fourth side opposite the third side;
a first doped well merging the second side with the fourth side;
a first channel region extending along a first direction over the first side;
first plunger gate structures and first barrier gate structures alternately arranged in the first channel region along the first direction, the first plunger gate structures each defining a first quantum bit region;
a second channel region extending along the first direction over the third side;
second plunger gate structures and second barrier gate structures alternately arranged in the second channel region along the first direction, the second plunger gate structures each defining a second quantum bit region; and
a second doped well disposed in the first substrate and adjacent to one of the first plunger gate structures along the first direction, the second doped well coupled to the first doped well.

11. The semiconductor device of claim 10, wherein the first doped well and the second doped well include a dopant of the same conductivity.

12. The semiconductor device of claim 10, further comprising:
a pair of first source/drain features over the first side, the first channel region interposed between the first source/drain features; and
a pair of second source/drain features over the third side, the second channel region interposed between the second source/drain features.

13. The semiconductor device of claim 10, wherein the first plunger gate structures each include a first gate electrode over a first gate dielectric layer, and wherein the second plunger gate structures each include a second gate electrode over a second gate dielectric layer.

14. The semiconductor device of claim 10, further comprising:
a pair of first gate spacers along sidewalls of each of the first plunger gate structures, each of the first gate spacers interposed between each of the first plunger gate structures and each of the first barrier gate structures; and
a pair of second gate spacers along sidewalls of each of the second plunger gate structures, each of the second gate spacers interposed between each of the second plunger gate structures and each of the second barrier gate structures.

15. The semiconductor device of claim 14, further comprising:
a first dielectric layer extending between each of the first gate spacers and a sidewall of each of the first barrier gate structures; and
a second dielectric layer extending between each of the second gate spacers and each of the second barrier gate structures, wherein the first dielectric layer and the second dielectric layer traverse a portion of the first channel region and a portion of the second channel region, respectively.

16. The semiconductor device of claim 10, further comprising:
a first through-substrate-via (TSV) extending from the first side to the second side across a top portion of the first doped well; and
a second TSV extending from the third side to the fourth side across a bottom portion of the first doped well, the first TSV directly coupled to the second TSV.

17. A method, comprising:
forming first source/drain features over a frontside of a first substrate, the first substrate having a backside opposite the frontside;
forming first plunger gates between the first source/drain features, the first plunger gates each defining a first quantum bit region over the frontside of the first substrate;
forming first barrier gates each interposed between two adjacent first plunger gates;
forming a first doped well over the backside of the first substrate;
forming second source/drain features over a frontside of a second substrate, the second substrate having a backside opposite the frontside;
forming second plunger gates between the second source/drain features, the second plunger gates each defining a second quantum bit region over the frontside of the second substrate;
forming second barrier gates each interposed between two adjacent second plunger gates;
forming a second doped well over the backside of the second substrate; and
merging the first doped well with the second doped well, thereby coupling the first substrate to the second substrate.

18. The method of claim 17, further comprising forming a third doped well in the first substrate adjacent to one of the first source/drain features, the third doped well extending vertically to contact the first doped well.

19. The method of claim 17, further comprising:
forming a first through-substrate-via (TSV) extending between the frontside and the backside of the first substrate; and
forming a second TSV extending between the frontside and the backside of the second substrate, the second TSV coupled to the first TSV.

20. The method of claim 17, further comprising:
forming a first dielectric layer separating a sidewall of each of the first plunger gates from a sidewall of each of the first barrier gates; and
forming a second dielectric layer separating a sidewall of each of the second plunger gates from a sidewall of each of the second barrier gates.
